(19) United States
(12) Patent Application Publication
(10) Pub. No.: US 2002/0036309 A1
(43) Pub. Date: Mar. 28, 2002

(54) Semiconductor device and method for fabricating the same

(76) Inventors: Mitsuru Sekiguchi, Shiga (JP); Takeshi Harada, Osaka (JP)

Correspondence Address: NIXON PEABODY, LLP, 8180 GREENSBORO DRIVE, SUITE 800, MCLEAN, VA, 22102, US

(21) Appl. No.: 09/924,120

(22) Filed: Aug. 8, 2001

(30) Foreign Application Priority Data
Aug. 24, 2000 (JP) 2000-253794

(51) Int. Cl. H01L 27/108

(52) U.S. Cl. 257/301; 257/305

(57) ABSTRACT

A barrier metal film of a metal whose conductivity will not be lost when the metal is oxidized or of a conductive metal oxide and a conductive wiring film of copper or a copper alloy are sequentially formed on a semiconductor substrate with an insulating film interposed therebetween.

### BACKGROUND OF THE INVENTION

The present invention generally relates to a semiconductor device having a copper wiring and a method for fabricating the same.

With increase in operation speed of transistors, the delay due to CR (capacitance-resistance) components of wirings has become a matter of concern in silicon LSIs (large scale integrated circuits) of 0.18 μm generation and the subsequent generations. Therefore, as a wiring material, Al (specific resistance of 3 μΩ·cm) is being increasingly replaced with Cu having a lower resistance (specific resistance of 1.7 μΩ·cm) or a metal primarily consisting of Cu (hereinafter, referred to as a “copper alloy”). Note that a wiring formed from copper or a copper alloy is herein referred to as a copper wiring.

Hereinafter, a conventional method for fabricating a semiconductor device will be described with reference to FIGS. 6A through 6E. Herein, the copper wiring fabricating technology using a Ta film (specific resistance of 200-230 μΩ·cm) as a barrier metal film is described by way of example.

First, as shown in FIG. 6A, a first wiring 13 of a copper film is embedded in a first insulating film 11 on a semiconductor substrate 10 with a first barrier metal film 12 of a Ta film interposed therebetween. Then, a first silicon nitride film 14, a second insulating film 15, a second silicon nitride film 16 and a third insulating film 17 are sequentially deposited on the semiconductor substrate 10. A via hole 18 reaching the first wiring 13 is then formed through the first silicon nitride film 14, second insulating film 15 and second silicon nitride film 16. A wiring trench 19 reaching the first wiring 13 through the via hole 18 is also formed in the third insulating film 17. The first barrier metal film 12 or the first silicon nitride film 14 prevents copper atoms of the first wiring 13 from diffusing into the first insulating film 11, the second insulating film 15 or the like due to the thermal processing at about 400° C. for depositing the second insulating film 15, the second silicon nitride film 16 or the like. In other words, the first barrier metal film 12 or the first silicon nitride film 14 serves as a barrier against diffusion of the copper atoms.

Then, as shown in FIG. 6B, a second barrier metal film 20 of a Ta film and a copper seed layer 21 of a copper film are sequentially deposited on the bottoms and wall surfaces of each of the via hole 18 and the wiring trench 19 by a sputtering process.

The semiconductor substrate 10 is then transferred from the sputtering apparatus into a plating apparatus. At this time, the surface of the semiconductor substrate 10, i.e., the surface of the copper seed layer 21, is exposed to the air. Then, as shown in FIG. 6C, a copper plating film 22 is grown on the copper seed layer 21 by an electroplating process so as to completely fill the via hole 18 and the wiring trench 19.

Thereafter, the copper plating film 22 is thermally processed (e.g., at about 100° C. for about two hours) in order to grow crystal grains of the copper plating film 22. Thus, as shown in FIG. 6D, the copper seed layer 21 and the copper plating film 22 are integrated into a wiring copper film 23.

As shown in FIG. 6E, those parts of the second barrier metal film 20 and the wiring copper film 23 which are located outside the wiring trench 19 are then removed to form a via 24 and a second wiring 25 from the wiring copper film 23. Thus, the first wiring 13 is connected to the second wiring 25 through the via 24.

Although not shown in the figure, a desired multi-layer wiring structure is then formed as necessary by repeatedly conducting the steps of FIGS. 6A through 6E (regarding FIG. 6A, the step of depositing the first silicon nitride film 14 and the subsequent steps).

In the conventional fabrication method of the semiconductor device, however, the copper seed layer 21 deposited by the sputtering process may have a reduced thickness on the wall surface of the via hole 18 due to the directivity of the sputtering process, as shown in FIG. 7A. Thus, those parts of the second barrier metal film 20 which are located on the wall surface of the via hole 18 may possibly be exposed. As described before, the surface of the semiconductor substrate 10 is exposed to the air during transfer thereof from the sputtering apparatus into the plating apparatus after deposition of the copper seed layer 21. Thus, if the second barrier metal film 20, i.e., the Ta film, has exposed parts, those parts will be exposed to the air and therefore oxidized. In this case, the resultant Ta oxide is a dielectric with very poor electric conductivity. Thus, when the copper plating film 22 is grown by electroplating to fill the via hole 18, an electric current does not flow through those oxidized parts of the second barrier metal film 20. This may result in filling defects such as voids in the via hole 18 or the like as shown in FIG. 7B. Those filling defects are induced even when a TaN film (specific resistance of 200-230 μΩ·cm), a Ti film (specific resistance of 50 μΩ·cm) or a TiN film (specific resistance of 200 μΩ·cm) is used as the second barrier metal film 20.

In order to fill a recess formed in the insulating film on the substrate with a copper film, a process such as a combination of sputtering and reflow processes, or a CVD (chemical vapor deposition) process may be used instead of the electroplating process.

Suppose that the combination of sputtering and reflow processes is used instead of the electroplating process and also that an oxidation-reduction reflow process (Proc. of the 42nd Annual Meeting of JSAP (Spring, 1995), p. 810, Cu Wiring Technology (1)—Reduced-Temperature Cu Reflow with Redox Cycle Reaction—)) is used as the ref low process in the combination of sputtering and reflow processes. In that case, a thick copper film is deposited by a sputtering process on the insulating film in which the recess is formed with a barrier metal film of, e.g., a Ta film interposed therebetween. The copper film is then repeatedly oxidized and reduced in an oxidative-reducing atmosphere by an oxidation-reduction reflow process. The resultant reaction heat causes the copper film to flow, thereby completely filling the recess. However, when the copper film is oxidized, the conductivity of the barrier metal film is substantially lost due to the oxidation thereof, i.e., the oxidation of the Ta film or the like. As a result, the resistance of the wiring, the via or the like as well as the barrier metal (which will be herein merely referred to as “wiring resistance”) will increase. The increase in wiring resistance is induced even when a copper film formed on the insulating film (which may have a recess therein) by the electroplating process, combination of sputtering and reflow processes, CVD process or the like is patterned into a wiring.

### SUMMARY OF THE INVENTION

A first object of the present invention is to enable a conductive film to be formed on a seed layer or a barrier metal film in a recess by an electroplating process, while preventing generation of filling defects.

A second object of the present invention is to prevent an increase in wiring resistance due to oxidation of the barrier metal film.

In order to achieve the first and second objects, a first semiconductor device according to the present invention includes an insulating film formed on a substrate and an embedded wiring of copper or a copper alloy formed in the insulating film. In the device, a barrier metal film of a metal whose conductivity will not be lost when the metal is oxidized or of a conductive metal oxide is formed between the insulating film and the embedded wiring.

In the first semiconductor device, the barrier metal film of a metal whose conductivity will not be lost when the metal is oxidized or of a conductive metal oxide is formed between the insulating film and the embedded wiring. Thus, when a conductive film which will be the embedded wiring is formed by an electroplating process, the following effects can be achieved. Suppose that the barrier metal film and a seed layer are sequentially deposited on wall surfaces of a recess (a wiring trench, a via hole or the like) formed in the insulating film. In that case, even when the barrier metal film has exposed parts due to poor coverage of the seed layer, it can be avoided that the conductivity of the exposed parts of the barrier metal film will be substantially lost due to the oxidation of its exposed part. This enables the formation of the conductive film on the seed layer or the barrier metal film located in the recess by the electroplating process, while preventing generation of filling defects. When the conductive film which will be the embedded wiring is formed by some process other than an electroplating process, the following effects can be achieved. That is to say, when the barrier metal film is deposited on wall surfaces of the recess and then the conductive film is formed on the barrier metal film, e.g., in an oxidative atmosphere, it can be avoided that the conductivity of the barrier metal film will be substantially lost due to the oxidation thereof. Thus, wiring resistance can be prevented from increasing due to the oxidation of the barrier metal film.

In order to achieve the second object, a second semiconductor device according to the present invention includes an insulating film formed on a substrate and a wiring of copper or a copper alloy formed on the insulating film. In the device, a barrier metal film of a metal whose conductivity will not be lost when the metal is oxidized or of a conductive metal oxide is formed between the insulating film and the wiring.

According to the second semiconductor device, the barrier metal film of a metal whose conductivity will not be lost when the metal is oxidized or of a conductive metal oxide is formed between the insulating film and the wiring. Thus, when the barrier metal film is deposited on the insulating film and then the conductive film for the wiring is formed on the barrier metal film, e.g., in an oxidative atmosphere, it can be avoided that the conductivity of the barrier metal film will be substantially lost due to the oxidation thereof. Thus, wiring resistance can be prevented from increasing due to the oxidation of the barrier metal film.

In the first and/or second semiconductor devices, the metal is preferably Ru, Ir or an alloy containing Ru or Ir.

Then, the barrier metal film can be prevented from substantially losing its conductivity due to the oxidation thereof as intended.

In the first and/or second semiconductor devices, the metal oxide is preferably RuO₂, IrO₂ or an alloy oxide containing Ru or Ir.

Then, the barrier metal film can be prevented from substantially losing its conductivity due to the oxidation thereof as intended.

In order to achieve the first object, a first process for fabricating a semiconductor device according to the present invention includes the steps of: forming a recess in an insulating film on a substrate; sequentially depositing a barrier metal film of a metal whose conductivity will not be lost when the metal is oxidized or of a conductive metal oxide and a first conductive film of copper or a copper alloy on wall surfaces of the recess; growing a second conductive film of copper or a copper alloy on the first conductive film by an electroplating process so as to completely fill the recess; and integrating the first and second conductive films into a third conductive film so as to form an embedded wiring of the third conductive film.

According to the first fabrication method, the barrier metal film of a metal whose conductivity will not be lost when the metal is oxidized or of a conductive metal oxide and the first conductive film are sequentially deposited on wall surfaces of the recess formed in the insulating film on the substrate. Thereafter, the second conductive film is grown on the first conductive film by the electroplating process so as to completely fill the recess. Then, the first and second conductive films are integrated into the third conductive film so as to form the embedded wiring of the third conductive film. Suppose that the barrier metal film and the first conductive film, i.e., the seed layer are sequentially deposited on wall surfaces of the recess. In that case, even when the barrier metal has exposed parts due to poor coverage of the seed layer, it can be avoided that the conductivity of the exposed parts of the barrier metal film will be substantially lost due to the oxidation of its exposed parts. This enables the formation of a second conductive film on the seed layer or the barrier metal film in the recess by the electroplating process, while preventing generation of filling defects.

In order to achieve the second object, a second process for fabricating a semiconductor device according to the present invention includes the steps of: sequentially depositing a barrier metal film of a metal whose conductivity will not be lost when the metal is oxidized or of a conductive metal oxide and a first conductive film of copper or a copper alloy on an insulating film overlying a substrate; growing a second conductive film of copper or a copper alloy on the first conductive film by an electroplating process; integrating the first and second conductive films into a third conductive film; and forming a wiring of the third conductive film by etching the third conductive film using a mask pattern covering a wiring forming region.

According to the second fabrication method, the barrier metal film of a metal whose conductivity will not be lost when the metal is oxidized or of a conductive metal oxide and the first conductive film are sequentially deposited. Thereafter, the second conductive film is grown on the first conductive film by the electroplating process. Then, the first and second conductive films are integrated into the third conductive film. The third conductive film is etched so as to form the wiring. Suppose that the barrier metal film and the first conductive film, i.e., the seed layer are sequentially deposited on the insulating film. In that case, even when the barrier metal film has exposed parts due to poor coverage of the seed layer, it can be avoided that the conductivity of the exposed parts of the barrier metal film will be substantially lost due to the oxidation of its exposed parts. Thus, wiring resistance can be prevented from increasing due to the oxidation of the barrier metal film.

In order to achieve the second object, a third process for fabricating a semiconductor device according to the present invention includes the steps of: forming a recess in an insulating film on a substrate; depositing a barrier metal film of a metal whose conductivity will not be lost when the metal is oxidized or of a conductive metal oxide on wall surfaces of the recess; and forming a conductive film of copper or a copper alloy on the barrier metal film to completely fill the recess and thereby forming an embedded wiring of the conductive film.

According to the third fabrication method, the barrier metal film of a metal whose conductivity will not be lost when the metal is oxidized or of a conductive metal oxide is deposited on wall surfaces of the recess formed in the insulating film on the substrate. Thereafter, the conductive film is formed on the barrier metal film so as to completely fill the recess. In this manner, the embedded wiring of the conductive film is formed. Thus, when the barrier metal film is deposited on wall surfaces of the recess and then the conductive film is formed on the barrier metal film, e.g., in an oxidative atmosphere, it can be avoided that the conductivity of the barrier metal film will be substantially lost due to the oxidation thereof. Thus, wiring resistance can be prevented from increasing due to the oxidation of the barrier metal film.

In order to achieve the second object, a fourth process for fabricating a semiconductor device according to the present invention includes the steps of: depositing a barrier metal film of a metal whose conductivity will not be lost when the metal is oxidized or of a conductive metal oxide on an insulating film overlying a substrate; forming a conductive film of copper or a copper alloy on the barrier metal film; and forming a wiring of the conductive film by etching the conductive film using a mask pattern covering a wiring forming region.

In the fourth fabrication method, the barrier metal film of a metal whose conductivity will not be lost when the metal is oxidized or of a conductive metal is deposited on the insulating film overlying the substrate. Thereafter, the conductive film is formed on the barrier metal film. Then, the wiring of the conductive film is formed by etching the conductive film. Thus, when the barrier metal film is deposited on the insulating film and then the conductive film is formed on the barrier metal film, e.g., in an oxidative atmosphere, it can be avoided that the conductivity of the barrier metal film will be substantially lost due to the oxidation thereof. Thus, wiring resistance can be prevented from increasing due to the oxidation of the barrier metal film.

In the third and/or fourth fabrication methods, the conductive film is preferably deposited by a sputtering process and then caused to flow in an oxidative-reducing atmosphere.

Then, the coverage of the conductive film is improved.

In the first, second, third and/or fourth fabrication methods, the metal is preferably Ru, Ir or an alloy containing Ru or Ir.

Then, the the barrier metal film can be prevented from substantially losing its conductivity due to the oxidation thereof as intended.

In the first, second, third and/or fourth fabrication methods, the metal oxide is preferably RuO₂, IrO₂ or an alloy oxide containing Ru or Ir.

Then, the the barrier metal film can be prevented from substantially losing its conductivity due to the oxidation thereof as intended.

### BRIEF DESCRIPTION OF THE DRAWINGS

FIGS. 1A through 1E are cross-sectional views illustrating respective steps of a method for fabricating a semiconductor device according to a first embodiment of the present invention.

FIGS. 2A through 2E are cross-sectional views illustrating respective steps of a method for fabricating a semiconductor device according to a second embodiment of the present invention.

FIGS. 3A through 3D are cross-sectional views illustrating respective steps of a method for fabricating a semiconductor device according to a third embodiment of the present invention.

FIGS. 4A through 4E are cross-sectional views illustrating some steps of a method for fabricating a semiconductor device according to a fourth embodiment of the present invention.

FIGS. 5A through 5D are cross-sectional views illustrating other steps of the method for fabricating a semiconductor device according to the fourth embodiment of the present invention.

FIGS. 6A through 6E are cross-sectional views illustrating respective steps of a conventional method for fabricating a semiconductor device.

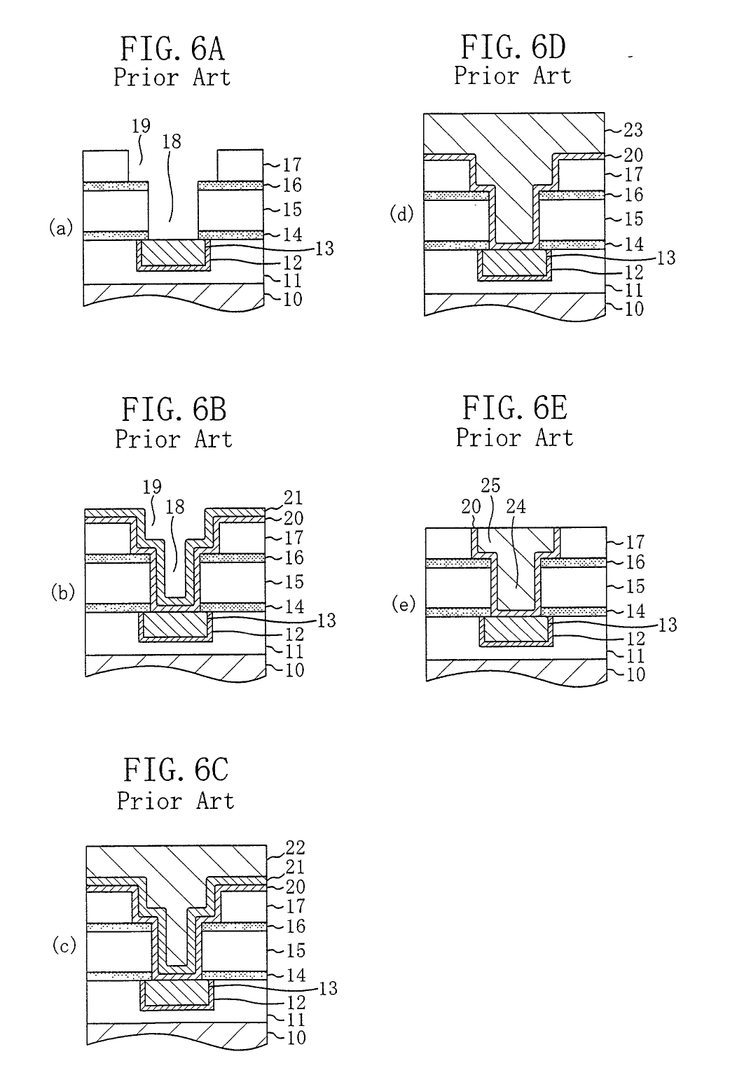

FIGS. 7A through 7B are cross-sectional views for describing problems of the conventional method for fabricating a semiconductor device.

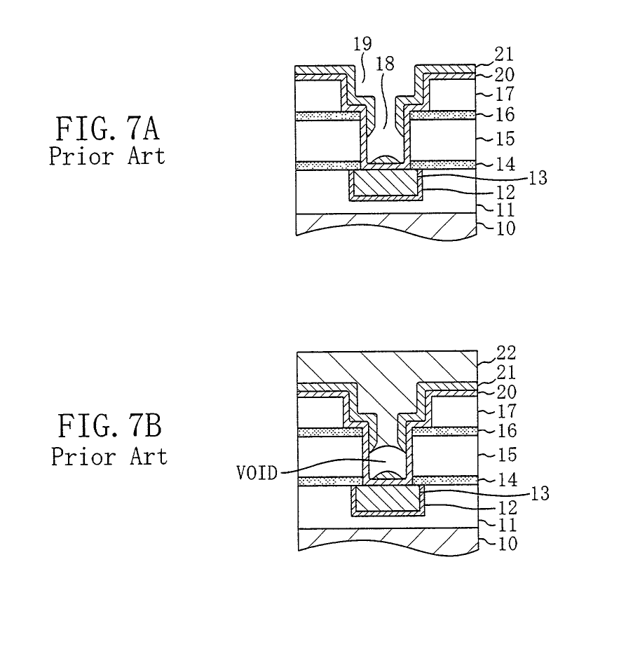

### DESCRIPTION OF THE PREFERRED EMBODIMENTS

Embodiment 1

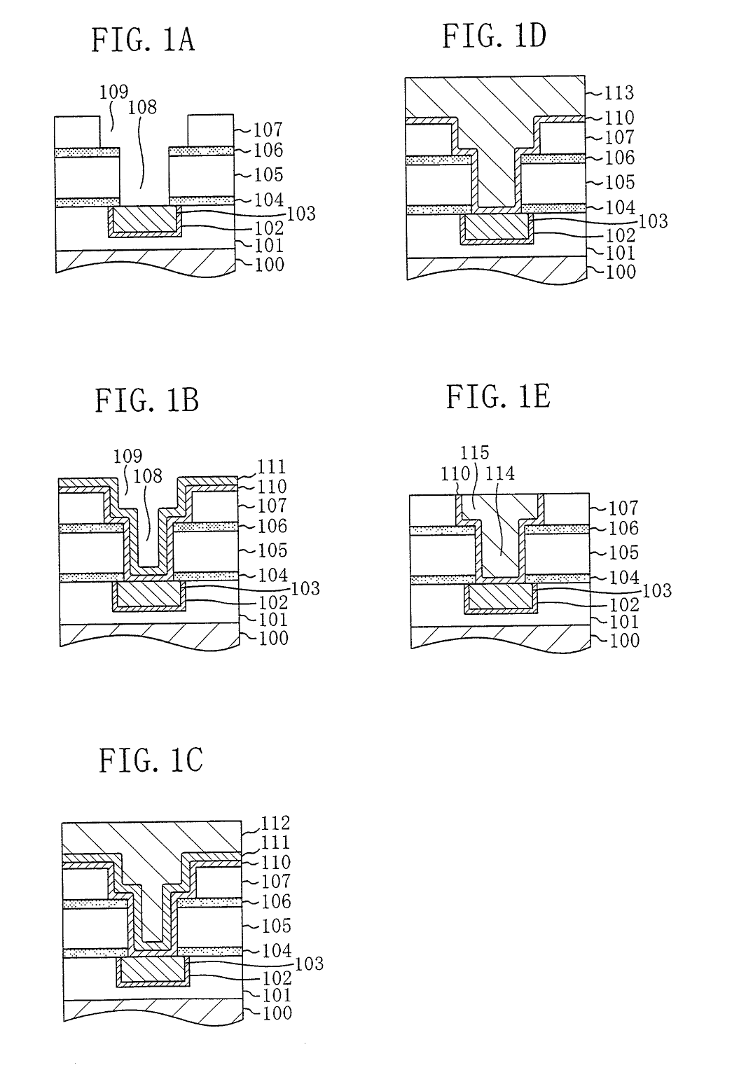

Hereinafter, a semiconductor device and a fabrication method thereof according to the first embodiment of the present invention will be described with reference to FIGS. 1A through 1E.

First, as shown in FIG. 1A, a first wiring 103 of, e.g., a copper film is embedded in a first insulating film 101 on a semiconductor substrate 100 with a first barrier metal film 102 of, e.g., a Ta film interposed therebetween. Then, a first silicon nitride film 104, a second insulating film 105, a second silicon nitride film 106 and a third insulating film 107 are sequentially deposited on the semiconductor substrate 100. A via hole 108 reaching the first wiring 103 is then formed through the first silicon nitride film 104, second insulating film 105 and second silicon nitride film 106. The via hole 108 has a depth of about 500 nm. A wiring trench 109 reaching the first wiring 103 through the via hole 108 is also formed in the third insulating film 107. The wiring trench 109 has a depth of about 300 nm. The first barrier metal film 102 or the first silicon nitride film 104 prevents copper atoms of the first wiring 103 from diffusing into the first insulating film 101, the second insulating film 105 or the like due to the thermal processing at about 400° C. (e.g., plasma CVD process) for depositing the second insulating film 105, the second silicon nitride film 106 or the like. In other words, the first barrier metal film 102 or the first silicon nitride film 104 serves as a barrier against diffusion of the copper atoms.

Next, as shown in FIG. 1B, a second barrier metal film 110 of a Ru (ruthenium) film is then deposited to a thickness of 25 nm on the semiconductor substrate 100 by, e.g., a sputtering process. Thereafter, a copper seed layer 111 of a copper film is deposited to a thickness of 150 nm on the second barrier metal film 110 by, e.g., a sputtering process. Thus, the bottoms and wall surfaces of each of the via hole 108 and the wiring trench 109 are covered with the second barrier metal film 110 and the copper seed layer 111.

The semiconductor substrate 100 is then transferred from the sputtering apparatus into a plating apparatus. At this time, if the second barrier metal film 110 has exposed parts due to the poor coverage of the copper seed layer 111, those parts will be exposed to the air and therefore oxidized. However, in this embodiment, the specific resistance of Ru of which the second barrier metal film 110 is made is 7.5 μΩ·cm, while the specific resistance of RuO₂, which is a Ru oxide, is 35 μΩ·cm. Therefore, even when the second barrier metal film 110 is oxidized, the conductivity thereof will not be lost.

Then, as shown in FIG. 1C, a copper plating film 112 is grown to a thickness of 500 nm on the copper seed layer 111 by an electroplating process so as to completely fill the via hole 108 and the wiring trench 109. More specifically, with the semiconductor substrate 100 being immersed in a plating solution including CuSO₄, H₂SO₄ and the like, the electroplating process is conducted such that the semiconductor substrate 100 has a negative potential. At this time, even if those parts of the second barrier metal film 110 which are located on the wall surfaces of the via hole 108 or the like are not covered with the copper seed layer 111, it can be avoided that the conductivity of the second barrier metal film 110 will be substantially lost due to oxidation thereof. Thus, the via hole 108 and the wiring trench 109 can be reliably filled with the copper plating film 112.

Thereafter, the semiconductor substrate 100 is removed from the plating apparatus, and then the copper plating film 112 is thermally processed (e.g., at about 100° C. for about two hours) in order to grow crystal grains of the copper plating film 112. As a result, the copper seed layer 111 and the copper plating film 112 are integrated into a wiring copper film 113 as shown in FIG. 1D. Note that, instead of thermally processing the copper plating film 112, the semiconductor substrate 100 may be left to stand at room temperature for about two days.

As shown in FIG. 1E, by for example a CMP (chemical mechanical polishing) process, those parts of the second barrier metal film 110 and the wiring copper film 113 which are located outside the wiring trench 109 are then removed to form a via 114 and a second wiring 115 from the wiring copper film 113. Thus, the first wiring 103 is connected to the second wiring 115 through the via 114.

Although not shown in the figure, a desired multi-layer wiring structure is then formed as necessary by repeatedly conducting the steps of FIGS. 1A through 1E (regarding FIG. 1A, the step of depositing the first silicon nitride film 104 and the subsequent steps).

As has been described above, according to the first embodiment, the second barrier metal film 110 of Ru, i.e., a “metal whose conductivity will not be lost when the metal oxidized” and the copper seed layer 111 are sequentially deposited on the bottoms and wall surfaces of each of the via hole 108 and the wiring trench 109. Thereafter, by an electroplating process, the copper plating film 112 is grown on the copper seed layer 111 so as to completely fill the via hole 108 and the wiring trench 109. Then, the copper seed layer 111 and the copper plating film 112 are integrated into the wiring copper film 113, so that the via 114 and the second wiring 115 are formed from the wiring copper film 113. Suppose that the second barrier metal film 110 and the copper seed layer 111 are sequentially deposited on the wall surfaces of the via hole 108 or the wiring trench 109. In that case, even when the second barrier metal film 110 has exposed parts due to poor coverage of the copper seed layer 111, it can be avoided that the conductivity of the exposed parts of the copper seed layer 111 will be substantially lost. This enables the formation of the copper plating film 112 on the copper seed layer 111 and the second barrier metal film 110 in the via hole 108 or the wiring trench 109 by an electroplating process, while preventing generation of filling defects. As a result, a margin of filling the via hole 108 or the wiring trench 109 with the copper plating film 112 is increased.

In the first embodiment, Ru is used as a material of the second barrier metal film 110. However, any “metal whose conductivity will not be lost when the metal is oxidized”, e.g., Ir (specific resistance 6.5 μΩ·cm: the specific resistance of IrO₂, which is an Ir oxide, is about 30 μΩ·cm), an alloy containing Ru or Ir may alternatively be used.

In the first embodiment, pure copper is used as a material of the first wiring 103, the copper seed layer 111 or the copper plating film 112. However, a copper alloy may alternatively be used.

In the first embodiment, a Ta film is used as the first barrier metal film 102. However, a TaN film, a Ti film, a TiN film or the like may alternatively be used.

In the first embodiment, an SiO₂ film, an SOG (Spin On Glass) film, a film which is deposited by using a CVD process, includes C and has a low dielectric constant, or the like may be used as the first insulating film 101, second insulating film 105 or third insulating film 107.

A dual damascene process in which the via hole 108 and the wiring trench 109 are simultaneously filled with a conductive film is used in the first embodiment. Alternatively, the via hole 108 and the wiring trench 109 may be separately formed and then separately filled with a conductive film.

In the first embodiment, in order to reduce the resistance of the first wiring 103 as well as the first barrier metal film 102 of a Ta film, some metal film other than a Ta film may be formed under the first barrier metal film 102.

In the first embodiment, in order to reduce the resistance of the via 114 or the second wiring 115 as well as the second barrier metal film 110 of a Ru film, some metal film other than a Ru film may be formed under the second barrier metal film 110.

Embodiment 2

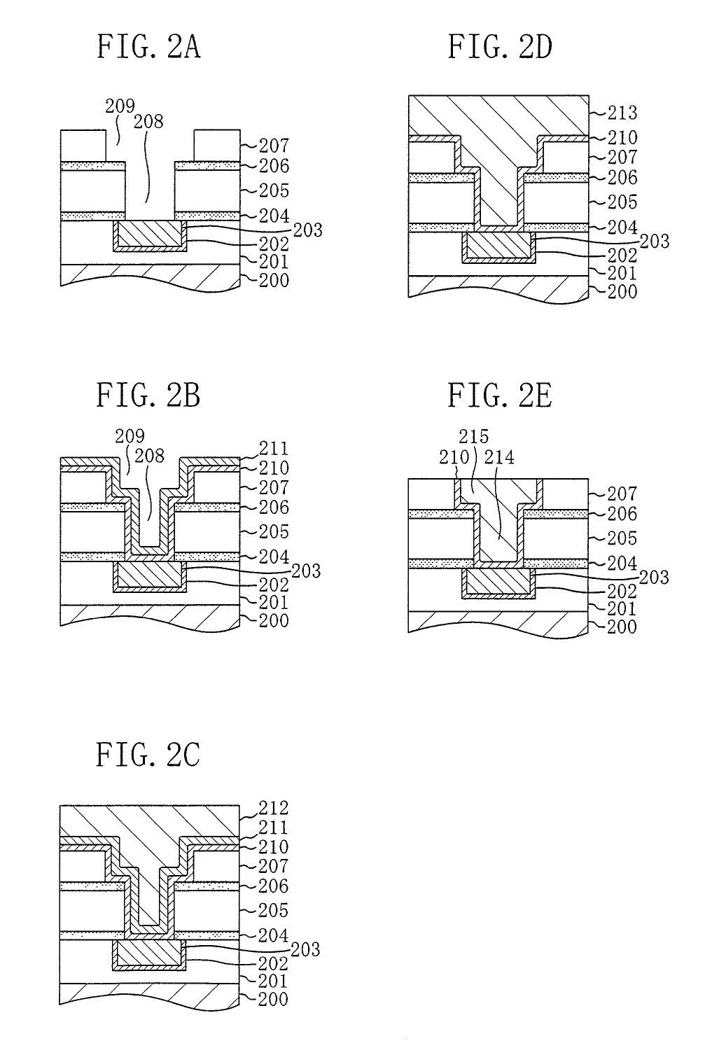

Hereinafter, a semiconductor device and a fabrication method thereof according to the second embodiment of the present invention will be described with reference to FIGS. 2A through 2E.

First, like the step of FIG. 1A in the first embodiment, as shown in FIG. 2A, a first wiring 203 of, e.g., a copper film is embedded in a first insulating film 201 on a semiconductor substrate 200 with a first barrier metal film 202 of, e.g., a Ta film interposed therebetween. Then, a first silicon nitride film 204, a second insulating film 205, a second silicon nitride film 206 and a third insulating film 207 are sequentially deposited on the semiconductor substrate 200. A via hole 208 reaching the first wiring 203 is then formed through the first silicon nitride film 204, second insulating film 205 and second silicon nitride film 206. The via hole 208 has a depth of about 500 nm. A wiring trench 209 reaching the first wiring 203 through the via hole 208 is also formed in the third insulating film 207. The wiring trench 209 has a depth of about 300 nm. The first barrier metal film 202 or the first silicon nitride film 204 prevents copper atoms of the first wiring 203 from diffusing into the first insulating film 201, the second insulating film 205 or the like due to the thermal processing at about 400° C. (e.g., plasma CVD process) for depositing the second insulating film 205, the second silicon nitride film 206 or the like. In other words, the first barrier metal film 202 or the first silicon nitride film 204 serves as a barrier against diffusion of the copper atoms.

Next, as shown in FIG. 2B, a second barrier metal film 210 of RuO₂ is deposited to a thickness of 25 nm on the semiconductor substrate 200 by, e.g., a reactive sputtering process in which sputtering is carried out using Ru as sputtering targets in an atmosphere of oxygen (O₂). Thereafter, a copper seed layer 211 of copper is deposited to a thickness of 150 nm on the second barrier metal film 210 by, e.g., a sputtering process. Thus, the bottoms and wall surfaces of each of the via hole 208 and the wiring trench 209 are covered with the second barrier metal 210 and the copper seed layer 211.

The semiconductor substrate 200 is then transferred from the sputtering apparatus into a plating apparatus. At this time, if the second barrier metal film 210 has exposed parts due to poor coverage of the copper seed layer 211, those parts will be exposed to the air. However, RuO₂ (specific resistance of 35 μΩ·cm) itself, of which the second barrier metal 210 is made, is a conductive metal oxide and thus will never cause further oxidation to substantially lose its conductivity.

Then, as shown in FIG. 2C, a copper plating film 212 is grown to a thickness of 500 nm on the copper seed layer 211 by an electroplating process so as to completely fill the via hole 208 and the wiring trench 209. More specifically, with the semiconductor substrate 200 being immersed in a plating solution including CuSO₄, H₂SO₄ and the like, the electroplating process is conducted such that the semiconductor substrate 200 has a negative potential. At this time, even if the second barrier metal film 210 on wall surfaces of the via hole 208 or the like is not covered with the copper seed layer 211, it can be avoided the conductivity of the second barrier metal film 210 will be substantially lost due to oxidation thereof. Thus, the via hole 208 and the wiring trench 209 can be reliably filled with the copper plating film 212.

Thereafter, the semiconductor substrate 200 is removed from the plating apparatus, and the copper plating film 212 is thermally processed (e.g., at about 100° C. for about two hours) in order to grow crystal grains of the copper plating film 212. As a result, the copper seed layer 211 and the copper plating film 212 are integrated into a wiring copper film 213 as shown in FIG. 2D. Note that, instead of thermally processing the copper plating film 212, the semiconductor substrate 200 may be left to stand at room temperature for about two days.

As shown in FIG. 2E, by, e.g., a CMP process, those parts of the second barrier metal film 210 and the wiring copper film 213 which are located outside the wiring trench 209 are then removed to form a via 214 and a second wiring 215 from the wiring copper film 213. Thus, the first wiring 203 is connected to the second wiring 215 through the via 214.

Although not shown in the figure, a desired multi-layer wiring structure is then formed as necessary by repeatedly conducting the steps of FIGS. 2A through 2E (regarding FIG. 2A, the step of depositing the first silicon nitride film 204 and the subsequent steps).

As has been described above, according to the second embodiment, the second barrier metal film 210 of RuO₂, i.e., a “conductive metal oxide” and the copper seed layer 211 are sequentially deposited on the bottoms and wall surfaces of each of the via hole 208 and the wiring trench 209. Thereafter, by an electroplating process, the copper plating film 212 is grown on the copper seed layer 211 so as to completely fill the via hole 208 and the wiring trench 209. Then, the copper seed layer 211 and the copper plating film 212 are integrated into the wiring copper film 213, so that the via 214 and the second wiring 215 are formed from the wiring copper film 213. Suppose that the second barrier metal film 210 and the copper seed layer 211 are sequentially deposited on the wall surface of the via hole 208 or wiring trench 209. In that case, even when the second barrier metal film 210 has exposed parts due to poor coverage of the copper seed layer 211, it can be avoided that the conductivity of the exposed parts will be substantially lost due to the oxidation thereof. This enables the formation of the copper plating film 212 on the copper seed layer 211 and the second barrier metal film 210 in the via hole 208 or the wiring trench 209 by an electroplating process, while preventing generation of filling defects. As a result, a margin of filling the via hole 208 or the wiring trench 209 with the copper plating film 212 is increased.

In the second embodiment, RuO₂ is used as a material of the second barrier metal film 210. However, any “conductive metal oxide”, e.g., IrO₂ (specific resistance of 30 μΩ·cm), an alloy oxide containing Ru or Ir, a superconducting oxide such as YBCO (YBa₂Cu₃O₇₋ₓ), or a compound such as La_{0.8}Sr_{0.2}MnO₃ may alternatively be used.

In the second embodiment, pure copper is used as a material of the first wiring 203, the copper seed layer 211 or the copper plating film 212. However, a copper alloy may alternatively be used.

In the second embodiment, a Ta film is used as the first barrier metal film 202. However, a TaN film, a Ti film, a TiN film or the like may alternatively be used.

In the second embodiment, an SiO₂ film, an SOG film, a CVD film including C and having a low dielectric constant, or the like may be used as the first insulating film 201, second insulating film 205 or third insulating film 207.

A dual damascene process in which the via hole 208 and the wiring trench 209 are simultaneously filled with a conductive film is used in the second embodiment. Alternatively, the via hole 208 and the wiring trench 209 may be separately formed and separately filled with a conductive film.

In the second embodiment, in order to reduce the resistance of the first wiring 203 as well as the first barrier metal film 202 of a Ta film, some metal film other than a Ta film may be formed under the first barrier metal film 202.

In the second embodiment, in order to reduce the resistance of the via 214 or the second wiring 215 as well as the second barrier metal film 210 of a RuO₂ film, some metal film other than a RuO₂ film under the second barrier metal film 210.

Embodiment 3

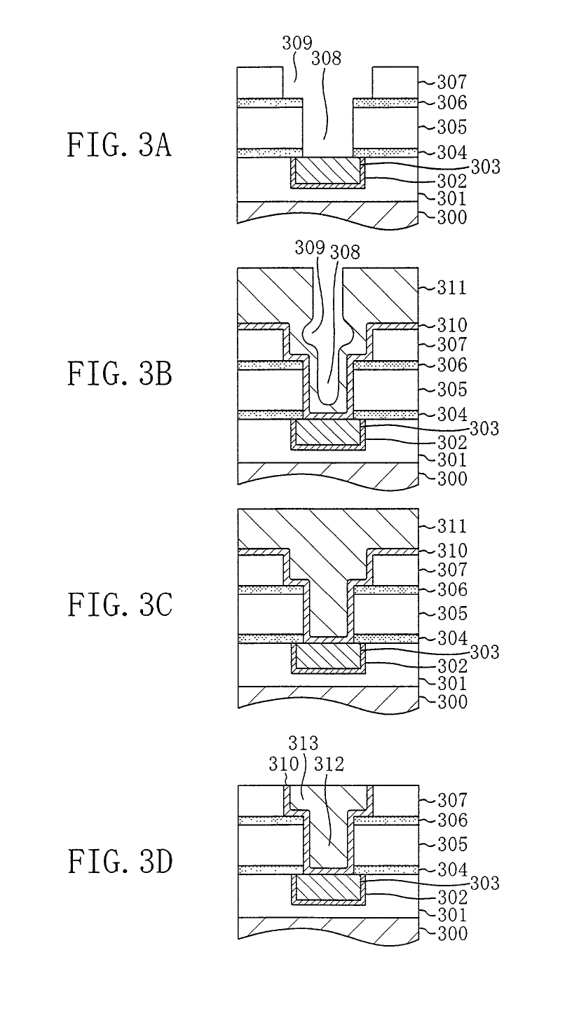

Hereinafter, a semiconductor device and a fabrication method thereof according to the third embodiment of the present invention will be described with reference to FIGS. 3A through 3D.

First, like the step of FIG. 1A in the first embodiment, as shown in FIG. 3A, a first wiring 303 of, e.g., a copper film is embedded in a first insulating film 301 on a semiconductor substrate 300 with a first barrier metal film 302 of, e.g., a Ta film interposed therebetween. Then, a first silicon nitride film 304, a second insulating film 305, a second silicon nitride film 306 and a third insulating film 307 are sequentially deposited on the semiconductor substrate 300. A via hole 308 reaching the first wiring 303 is then formed through the first silicon nitride film 304, second insulating film 305 and second silicon nitride film 306. The via hole 308 has a depth of about 500 nm. A wiring trench 309 reaching the first wiring 303 through the via hole 308 is also formed in the third insulating film 307. The wiring trench 309 has a depth of about 300 nm. The first barrier metal film 302 or the first silicon nitride film 304 prevents copper atoms of the first wiring 303 from diffusing into the first insulating film 301, the second insulating film 305 or the like due to the thermal processing at about 400° C. (e.g., plasma CVD process) for depositing the second insulating film 305, the second silicon nitride film 306 or the like. In other words, the first barrier metal film 302 or the first silicon nitride film 304 serves as a barrier against diffusion of the copper atoms.

As shown in FIG. 3B, a second barrier metal film 310 of, e.g., a Ru film is then deposited on the semiconductor substrate 300 to a thickness of 25 nm by, e.g., a sputtering process. Accordingly, the bottoms and wall surfaces of each of the via hole 308 and the wiring trench 309 are covered with the second barrier metal film 310. Thereafter, a wiring copper film 311 is deposited to a thickness of 600 nm on the second barrier metal film 310 by, e.g., a sputtering process. At this time, the via hole 308 or the wiring trench 309 cannot completely be filled with the wiring copper film 311 due to the directivity of the sputtering process, as shown in FIG. 3B.

As shown in FIG. 3C, the wiring copper film 311 is then repeatedly oxidized and reduced in an oxidative-reducing atmosphere by, e.g., an oxidation-reduction reflow process. The resultant reaction heat causes the wiring copper film 311 to flow, thereby completely filling the via hole 308 or the wiring trench 309. Note that, upon oxidizing the wiring copper film 311, the second barrier metal 310 is also oxidized simultaneously. However, the specific resistance of Ru of which the second barrier metal film 310 is made is 7.5 μΩ·cm, while the specific resistance of an Ru oxide, RuO₂ is 35 μΩ·cm. Therefore, the second barrier metal film 310 will not lose its conductivity when oxidized.

As shown in FIG. 3D, by, e.g., a CMP process, those parts of the second barrier metal film 310 and the wiring copper film 311 which are located outside the wiring trench 309 are then removed to form a via 312 and a second wiring 313 from the wiring copper film 311. Thus, the first wiring 303 is connected to the second wiring 313 through the via 312.

Although not shown in the figure, a desired multi-layer wiring structure is then formed as necessary by repeatedly conducting the steps of FIGS. 3A through 3D (regarding FIG. 3A, the step of depositing the first silicon nitride film 304 and the subsequent steps).

As has been described above, according to the third embodiment, the second barrier metal film 310 of Ru, i.e., a “metal whose conductivity will not be lost when the metal is oxidized” is deposited on the bottoms and wall surfaces of each of the via hole 308 and the wiring trench 309. Thereafter, the wiring copper film 311 is formed on the second barrier metal film 310 so as to completely fill the via hole 308 and the wiring trench 309. In this manner, the via 312 and the second wiring 313 are formed. Accordingly, even when the second barrier metal film 310 is deposited on the wall surfaces of the via hole 308 or the wiring trench 309 and then the wiring copper film 311 is formed on the second barrier metal film 310, e.g., in an oxidative atmosphere, it can be avoided that the conductivity of the second barrier metal film 310 will not be lost due to the oxidation thereof. Thus, the resistance of the via 312 or the second wiring 313 as well as the second barrier metal film 310 can be prevented from increasing due to the oxidation of the second barrier metal film 310.

In the third embodiment, Ru is used as a material of the second barrier metal film 310. However, any “metal whose conductivity will not be lost when the metal is oxidized”, e.g., Ir or an alloy containing Ru or Ir may alternatively be used. Also, instead of a “metal whose conductivity will not be lost when the metal is oxidized”, a “conductive metal oxide”, e.g., RuO₂, IrO₂, an alloy oxide containing Ru or Ir, a superconducting oxide such as YBCO, or a compound such as La_{0.8}Sr_{0.2}MnO₃ may alternatively be used.

In the third embodiment, pure copper is used as a material of the first wiring 303 or the copper seed layer 311. However, a copper alloy may alternatively be used.

In the third embodiment, a Ta film is used as the first barrier metal film 302. However, a TaN film, a Ti film, a TiN film or the like may alternatively be used.

In the third embodiment, an SiO₂ film, an SOG film, a CVD film including C and having a low dielectric constant, or the like may be used as the first insulating film 301, second insulating film 305 or third insulating film 307.

In the third embodiment, in order to form the wiring copper film 311, a combination of sputtering and reflow processes is used. However, a CVD process, an electroless plating process, an ion plating process, a combination of CVD and high-temperature sputtering processes (a process in which after a thin copper film has been deposited by a CVD process, a thick copper film is deposited on the thin film by a high-temperature sputtering process) or the like may alternatively used. Also, in this embodiment, an oxidative-reducing reflow process is used as the reflow process in the combination of sputtering and reflow processes. However, some other reflow process may alternatively be used.

A dual damascene process in which the via hole 308 and the wiring trench 309 are simultaneously filled with a conductive film is used in the third embodiment. Alternatively, the via hole 308 and the wiring trench 309 may be separately formed and separately filled with a conductive film.

In the third embodiment, in order to reduce the resistance of the first wiring 303 as well as the first barrier metal film 302 of a Ta film, some metal film other than a Ta film may be formed under the first barrier metal film 302.

In the third embodiment, in order to reduce the resistance of the via 312 or the second wiring 313 as well as the second barrier metal film 310 of a Ru film, some metal film other than a Ru film under the second barrier metal film 310.

Embodiment 4

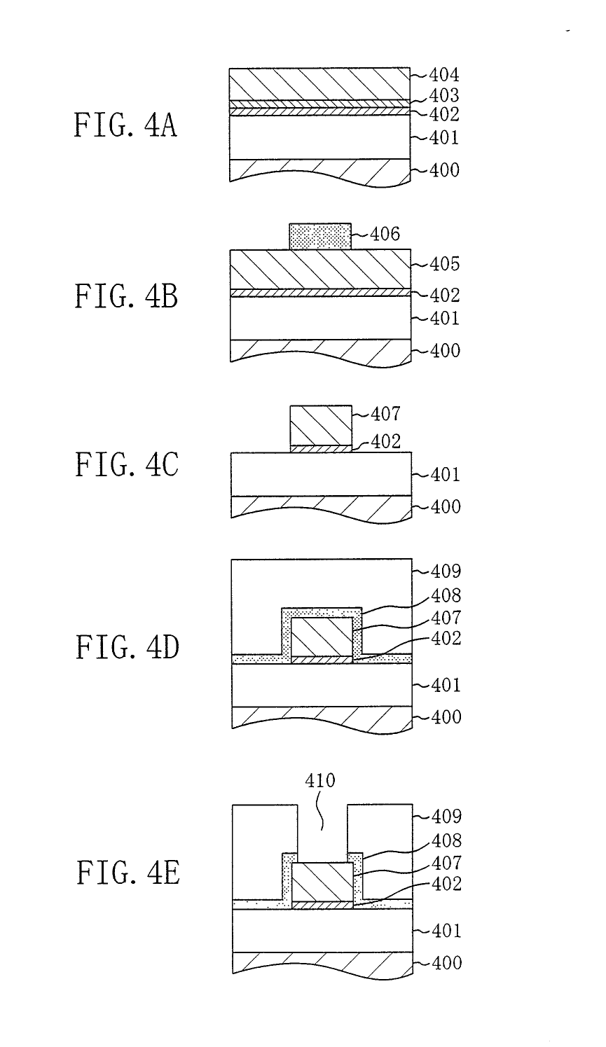

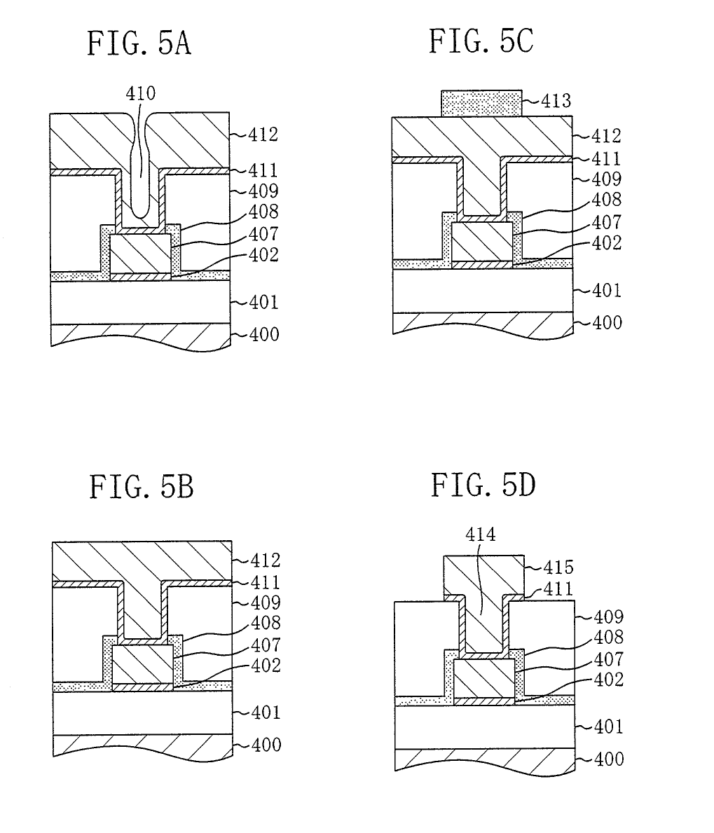

Hereinafter, a semiconductor device and a fabrication method thereof according to the fourth embodiment of the present invention will be described with reference to FIGS. 4A through 4E and FIGS. 5A through 5D.

First, as shown in FIG. 4A, a first barrier metal film 402 of a Ru film is deposited on a first insulating film 401 overlying a semiconductor substrate 400 to a thickness of 10 nm by, e.g., a sputtering process. Thereafter, a copper seed layer 403 of a copper film is deposited to a thickness of 100 nm on the first barrier metal film 402 by, e.g., a sputtering process.

The semiconductor substrate 400 is then transferred from the sputtering apparatus into a plating apparatus. At this time, if the first barrier metal film 402 has exposed parts due to the poor coverage of the copper seed layer 403, those parts will be exposed to the air and therefore oxidized. However, in this embodiment, the specific resistance of Ru of which the first barrier metal film 402 is made is 7.5 μΩ·cm, while the specific resistance of RuO₂, which is a Ru oxide, is 35 μΩ·cm. Thus, even when the first barrier metal film 402 is oxidized, the conductivity thereof will not be lost.

Then, as shown in FIG. 4A, a copper plating film 404 is grown to a thickness of 500 nm on the copper seed layer 403 by an electroplating process. More specifically, with the semiconductor substrate 400 being immersed in a plating solution including CuSO₄, H₂SO₄ and the like, the electroplating process is conducted such that the semiconductor substrate 400 has a negative potential. Note that, although not shown in the figure, in the case where the first insulating film 401 has a recess such as a contact hole or via hole, the recess is filled with the copper plating film 404 with the first barrier metal film 402 and the copper seed layer 403 interposed therebetween.

Thereafter, the semiconductor substrate 400 is removed from the plating apparatus, and the copper plating film 404 is thermally processed (e.g., at about 100° C. for about two hours) in order to grow crystal grains of the copper plating film 404. As a result, the copper seed layer 403 and the copper plating film 404 are integrated into a first wiring copper film 405, as shown in FIG. 4B. Note that, instead of thermally processing the copper plating film 404, the semiconductor substrate 400 may be left to stand at room temperature for about two days.

As shown in FIG. 4B, a first resist pattern 406 is then formed on the first wiring copper film 405 so as to cover a first wiring forming region.

Next, by using the first resist pattern 406 as a mask, the first wiring copper film 405 and the first barrier metal film 402 are sequentially etched to form a first wiring 407 on the first insulating film 401 with the first barrier metal film 402 interposed therebetween, as shown in FIG. 4C.

Thereafter, as shown in FIG. 4D, a silicon nitride film 408 and a second insulating film 409 are sequentially deposited on the first wiring 407 and the first insulating film 401. As a result, the top and side surfaces of the first wiring 407 are covered with the second insulating film 409 with the silicon nitride film 408 interposed therebetween. The first barrier metal film 402 or the silicon nitride film 408 prevents copper atoms of the first wiring 407 from diffusing into the first insulating film 401, the second insulating film 409 or the like due to the thermal processing at about 400° C. (e.g., plasma CVD process) for depositing the second insulating film 409 or the like. In other words, the first barrier metal film 402 or the silicon nitride film 408 serves as a barrier against diffusion of the copper atoms.

As shown in FIG. 4E, a via hole 410 reaching the first wiring 407 is then formed through the silicon nitride film 408 and the second insulating film 409. The via hole 410 has a depth of about 500 nm.

As shown in FIG. 5A, a second barrier metal film 411 of a Ru film is then deposited to a thickness of 25 nm on the second insulating film 409 as well as in the via hole 410 by, e.g., a sputtering process. Thus, the bottom and wall surface of the via hole 410 are covered with the second barrier metal film 411.

Thereafter, a second wiring copper film 412 is deposited to a thickness of 600 nm on the second barrier metal film 411 by, e.g., a sputtering process. At this time, the via hole 410 cannot completely be filled with the second wiring copper film 412 due to the directivity of the sputtering process, as shown in FIG. 5A.

As shown in FIG. 5B, the second wiring copper film 412 is then repeatedly oxidized and reduced in an oxidative-reducing atmosphere by, e.g., an oxidation-reduction reflow process. The resultant reaction heat causes the second wiring copper film 412 to flow, thereby completely filling the via hole 410. Note that, upon oxidizing the second wiring copper film 412, the second barrier metal film 411 is also oxidized simultaneously. However, the specific resistance of Ru of which the second barrier metal film 411 is made is 7.5 μΩ·cm, while the specific resistance of RuO₂, which is a Ru oxide, is 35 μΩ·cm. Thus, even when the second barrier metal film 411 is oxidized, the conductivity thereof will not be lost.

As shown in FIG. 5C, a second resist pattern 413 is then formed on the second wiring copper film 412 so as to cover a second wiring forming region. By using the second resist pattern 413 as a mask, the second wiring copper film 412 and the second barrier metal film 411 are sequentially etched to form a via 414 and a second wiring 415 from the second wiring copper film 412, as shown in FIG. 5D. Thus, the first wiring 407 is connected to the second wiring 415 through the via 414.

Although not shown in the figure, a desired multi-layer wiring structure is then formed as necessary by repeatedly conducting the steps of FIGS. 4D and 4E and FIGS. 5A through 5D.

As has been described above, according to the fourth embodiment, the first barrier metal film 402 of Ru, i.e., a “metal whose conductivity will not be lsot when the metal is oxidized,” and the copper seed layer 403 are sequentially deposited on the first insulating film 401. Thereafter, by an electroplating process, the copper plating film 404 is grown on the copper seed layer 403. Then, the copper seed layer 403 and the copper plating film 404 are integrated into the first wiring copper film 405. The first wiring copper film 405 is etched to form the first wiring 407. Suppose that the first barrier metal film 402 and the copper seed layer 403 are sequentially deposited on the first insulating film 401. In that case, even when the first barrier metal film 402 has exposed parts due to poor coverage of the copper seed layer 403, it can be avoided that the conductivity of the exposed parts will be substantially lost due to the oxidation thereof. Therefore, the resistance of the first wiring 407 as well as the first barrier metal film 402 can be prevented from increasing due to the oxidation of the first barrier metal film 402.

In the fourth embodiment, the second barrier metal film 411 of Ru, i.e., a “metal whose conductivity will not be lost when the metal is oxidized,” is deposited on the second insulating film 409 as well as in the via hole 410. Thereafter, the second wiring copper film 412 is formed on the second barrier metal 411 so as to completely fill the via hole 410. Then, the second wiring copper film 412 is etched to form the via 414 and the second wiring 415. Thus, even when the second barrier metal film 411 is deposited on the second insulating film 409 and then the second wiring copper film 412 is formed on the second barrier metal film 411, e.g., in an oxidative atmosphere, it can be avoided that the conductivity of the second barrier metal film 411 will be substantially lost due to the oxidation thereof. Therefore, the resistance of the via 414 or the second wiring 415 as well as the second barrier metal film 411 can be prevented from increasing due to the oxidation of the second barrier metal film 411.

In the fourth embodiment, Ru is used as a material of the first barrier metal film 402 or the second barrier metal film 411. However, any “metal whose conductivity will not be lost when the metal is oxidized”, e.g., Ir or an alloy containing Ru or Ir may alternatively be used. Also, instead of a “metal whose conductivity will not be lost when the metal is oxidized”, a “conductive metal oxide”, e.g., RuO₂, IrO₂, an alloy oxide containing Ru or Ir, a superconducting oxide such as YBCO, or a compound such as La_{0.8}Sr_{0.2}MnO₃ may alternatively be used.

In the fourth embodiment, pure copper is used as a material of the copper seed layer 403, the copper plating film 404 or the second wiring copper film 412. However, a copper alloy may alternatively be used.

In the fourth embodiment, an SiO₂ film, an SOG film, a CVD film including C and having a low dielectric constant, or the like may be used as the first insulating film 401 or second insulating film 409.

In the fourth embodiment, in order to form the second wiring copper film 412, the combination of sputtering and reflow processes is used. However, a CVD process, an electroless plating process, an ion plating process, a combination of CVD and high temperature sputtering processes or the like may alternatively used. Also, in this embodiment, an oxidative-reducing reflow process is used as the reflow process in the combination of sputtering and reflow processes. However, some other reflow process may alternatively be used.

In the fourth embodiment, in order to reduce the resistance of the first wiring 407 as well as the first barrier metal film 402 of a Ru film, some metal film other than a Ru film may be formed under the first barrier metal film 402.

In the fourth embodiment, in order to reduce the resistance of the via 414 or the second wiring 415 as well as the second barrier metal film 411 of a Ru film, some metal film other than a Ru film under the second barrier metal film 411.

What is claimed is:

1. A semiconductor device, comprising:
an insulating film formed on a substrate; and
an embedded wiring of copper or a copper alloy formed in the insulating film,
wherein a barrier metal film of a metal whose conductivity will not be lost when the metal is oxidized or of a conductive metal oxide is formed between the insulating film and the embedded wiring.

2. The device of claim 1, wherein the metal is Ru, Ir or an alloy containing Ru or Ir.

3. The device of claim 1, wherein the metal oxide is RuO₂, IrO₂ or an alloy oxide containing Ru or Ir.

4. A semiconductor device, comprising:
an insulating film formed on a substrate; and
a wiring of copper or a copper alloy formed on the insulating film,
wherein a barrier metal film of a metal whose conductivity will not be lost when the metal is oxidized or of a conductive metal oxide is formed between the insulating film and the wiring.

5. The device of claim 4, wherein the metal is Ru, Ir or an alloy containing Ru or Ir.

6. The device of claim 4, wherein the metal oxide is RuO₂, IrO₂ or an alloy oxide containing Ru or Ir.

7. A method for fabricating a semiconductor device, comprising the steps of:
forming a recess in an insulating film on a substrate;
sequentially depositing a barrier metal film of a metal whose conductivity will not be lost when the metal is oxidized or of a conductive metal oxide and a first conductive film of copper or a copper alloy on wall surfaces of the recess;
growing a second conductive film of copper or a copper alloy on the first conductive film by an electroplating process so as to completely fill the recess; and
integrating the first and second conductive films into a third conductive film so as to form an embedded wiring of the third conductive film.

8. The method of claim 7, wherein the metal is Ru, Ir or an alloy containing Ru or Ir.

9. The method of claim 7, wherein the metal oxide is RuO₂, IrO₂ or an alloy oxide containing Ru or Ir.

10. A method for fabricating a semiconductor device, comprising the steps of:
sequentially depositing a barrier metal film of a metal whose conductivity will not be lost when the metal is oxidized or of a conductive metal oxide and a first conductive film of copper or a copper alloy on an insulating film overlying a substrate;
growing a second conductive film of copper or a copper alloy on the first conductive film by an electroplating process;
integrating the first and second conductive films into a third conductive film; and
forming a wiring of the third conductive film by etching the third conductive film using a mask pattern covering a wiring forming region.

11. The method of claim 10, wherein the metal is Ru, Ir or an alloy containing Ru or Ir.

12. The method of claim 10, wherein the metal oxide is RuO₂, IrO₂ or an alloy oxide containing Ru or Ir.

13. A method for fabricating a semiconductor device, comprising the steps of:
forming a recess in an insulating film on a substrate;
depositing a barrier metal film of a metal whose conductivity will not be lost when the metal is oxidized or of a conductive metal oxide on wall surfaces of the recess; and
forming a conductive film of copper or a copper alloy on the barrier metal film to completely fill the recess and thereby forming an embedded wiring of the conductive film.

14. The method of claim 13, wherein the conductive film is deposited by a sputtering process and then caused to flow in an oxidative-reducing atmosphere.

15. The method of claim 13, wherein the metal is Ru, Ir or an alloy containing Ru or Ir.

16. The method of claim 13, wherein the metal oxide is RuO₂, IrO₂ or an alloy oxide containing Ru or Ir.

17. A method for fabricating a semiconductor device, comprising the steps of:
depositing a barrier metal film of a metal whose conductivity will not be lost when the metal is oxidized or of a conductive metal on an insulating film overlying a substrate;
forming a conductive film of copper or a copper alloy on the barrier metal film; and
forming a wiring of the conductive film by etching the conductive film using a mask pattern covering a wiring forming region.

18. The method of claim 17, wherein the conductive film is deposited by a sputtering process and then caused to flow in an oxidative-reducing atmosphere.

19. The method of claim 17, wherein the metal is Ru, Ir or an alloy containing Ru or Ir.

20. The method of claim 17, wherein the metal oxide is RuO₂, IrO₂ or an alloy oxide containing Ru or Ir.
